(19) United States
(12) Patent Application Publication
(10) Pub. No.: US 2001/0033196 A1
(43) Pub. Date: Oct. 25, 2001

(54) State variable filter including a programmable variable resistor

(75) Inventors: Paul A. Lennous, Austin, TX (US); Alvin G. Becker, Austin, TX (US); Prahalad K. Vasudev, Austin, TX (US)

Correspondence Address: Jeffrey C. Hood, Conley, Rose, & Tayon, P.C., P.O. Box 398, Austin, TX, 78767, US

(73) Assignee: National Instruments Corporation

(21) Appl. No.: 09/839,454

(22) Filed: Apr. 20, 2001

Related U.S. Application Data
(62) Division of application No. 09/488,165, filed on Jan. 20, 2000.

(51) Int. Cl. H03B 1/00

(52) U.S. Cl. 327/552

(57) ABSTRACT

An active state variable filter is presented including a summing circuit, a first and second integrator circuits, and an amplifier circuit. The summing circuit and first and second integrator circuits each include a programmable variable resistor for programmably varying the filtering characteristics of the state variable filter. Each programmable variable resistor receives a digital value and provides an electrical resistance corresponding to the digital value between a pair of terminals. Each programmable variable resistor may include multiple branch circuits extending between the pair of terminals, each branch circuit including an electrical resistor and an electrical switch connected in series. Alternately, each programmable variable resistor may include multiple subcircuits connected in series between the pair of terminals, each subcircuit including an electrical resistor and an electrical switch connected in parallel. Each programmable variable resistor may also include a memory unit for storing the digital value, and control logic for controlling the electrical switches dependent upon the digital value. The electrical switches may be bilateral switches such as microelectromechanical systems (MEMS) switches. An instrumentation system is also presented comprising a signal conditioning subsystem including the state variable filter.

This Application is a Divisional of U.S. utility application Ser. No. 09/488,165 titled “State Variable Filter Including a Programmable Variable Resistor” filed Jan. 20, 2000, whose inventors were Paul A. Lennous, Alvin G. Becker, and Prahalad K. Vasudev.

### BACKGROUND OF THE INVENTION

1. Field of the Invention

The present invention relates to state variable filters used to filter analog signals, and more particularly to an improved state variable filter including a programmable variable resistor to reduce generated noise voltages.

2. Description of the Related Art

Scientists and engineers often use instrumentation or data acquisition (DAQ) systems to obtain measurement data pertaining to physical phenomena (e.g., force, pressure, acceleration, etc.). Such measurement data is useful in laboratory research and testing, process monitoring and control, and control of mechanical or electrical machinery, to name a few examples. A typical analog instrumentation system includes signal conditioning circuitry which performs one or more “signal conditioning” functions upon analog measurement signals. Such signal conditioning functions include amplification, filtering, and direct current (d.c.) level shifting.

In general, signal filters pass signal frequencies within a pass band and attenuate signal frequencies within a stop band outside of the pass band. A “cutoff frequency” or “corner frequency” f_{c} defines a boundary between the pass band and the stop band. Common types of signal filters include low pass, high pass, and band pass filters. The pass band of a low pass filter extends from d.c. (0 Hz) to fc, and the stop band of a low pass filter lies above fc. A high pass filter has a pass band above fc, and a stop band including frequencies below fc. Graphs of ratios of output voltage to input voltage versus frequency for real (i.e., non-ideal) low and high pass filters have finite slopes within the stop bands. Low pass and high pass filters have quality factors or “Qs” which determine the slopes of such graphs within the stop bands.

Band pass filters have a pass band extending between a low corner frequency fl and a high corner frequency fh. Low corner frequency fl defines a boundary between the pass band and a first stop band including frequencies below fl, and high corner frequency fh defines a boundary between the pass band and a second stop band including frequencies above fh. A band pass filter has a center frequency fo representing a geometric mean of fh and fl, a bandwidth bw, and a selectivity or Q, where:

$$fo = \sqrt{fh \cdot fl} , \\ bw = fh - fl , and$$

$$Q = \frac{fo}{bw}$$

Active filters typically use operational amplifiers (i.e., op amps), along with resistors and capacitors, to implement a desired signal filter. Active filters are able to provide signal gains of greater than unity. A state variable filter is a versatile type of active filter circuit which provides low pass, high pass, and band pass outputs simultaneously. State variable filters are second order filters, having two “poles” at frequencies where denominators of transfer functions of the state variable filters are equal to zero. Multiple second order state variable filter stages may be cascaded to achieve additional signal attenuation within stop bands.

As filtering requirements change from application to application, it is highly desirable to be able to vary the characteristics of active filters (e.g., state variable filters) without having to replace resistors and/or capacitors with like components having different values. FIG. 1 is a circuit diagram of an exemplary prior art state variable filter 10 having digitally programmable characteristics. State variable filter 10 includes four programmable multiplying digital to analog converters (MDACs) paired with op amps to form programmable inverting voltage attenuators. Digital values provided to and stored within the MDACs determine the corner frequencies fc of the low and high pass outputs (center frequency fo of the band pass output), the voltage gain G provided within the pass bands, and the Q of the low, high, and band pass outputs.

MDAC1 is coupled to op amp OA1 to provide unipolar operation, resulting in 2 -quadrant multiplication. MDAC1 receives an input signal V_{IN} at a reference voltage (V_{REF}) terminal and n binary digits (bits) of a digital value D1, where n≧0. MDAC1 produces an output current coupled to an inverting input terminal of OA1 labeled “−” in FIG. 1. A non-inverting input terminal of OA1 labeled “+” is connected to a reference ground electrical potential. OA1 produces an output voltage Vi at an output terminal. Output voltage V1 is fed back to a feedback terminal (R_{FB}) of MDAC1. As a result,

$$V1 = - {V}_{IN} \cdot ( \frac{D1}{{2}^{n}} )$$

Thus the combination of MDAC1 and OA1 forms a programmable inverting voltage attenuator. Digital value D1 determines high pass gain G:

$$G = ( \frac{R4}{R5} ) ( \frac{D1}{{2}^{n}} )$$

Op amp OA5 functions as an inverting summing amplifier, and produces the high pass output at an output terminal. Op amps OA6 and OA7 are configured to function as inverting integrators with time constants equal to the product of resistance values R1, coupled to the inverting input terminals, and feedback capacitance values C1. MDAC2 is programmed by n bits of a digital value D2, and combined with OA2 forms a programmable inverting voltage attenuator. The high pass output signal produced by OA5 is provided to the input V_{REF} terminal of MDAC2, and the output of OA2 feeds inverting integrator OA6 through resistance value R1. The attenuating action at the input of the inverting regulator causes the combined pair to act as an integrator with a programmable time constant t₂, where:

$${t}_{2} = \frac{{R}_{1} \cdot {C}_{1} \cdot {2}^{n}}{D2}$$

OA6 produces the band pass output at an output terminal. The band pass output signal produced by OA6 is provided to the input V_{REF} terminal of MDAC3. MDAC3 is programmed by n bits of a digital value D3, and combined with OA3 forms another programmable inverting voltage attenuator. The output of OA3 feeds inverting integrator OA7 through resistance value R1. Thus MDAC3, OA3, and OA7 form another programmable time constant integrator. OA7 produces the low pass output at an output terminal. When D2=D3=D,

$$fc = fo = ( \frac{1}{2 π R1C1} ) ( \frac{D}{{2}^{n}} )$$

MDAC4 receives and stores n bits of a digital value D4 which determines the Q of the low, high, and band pass outputs. MDAC4 receives the band pass output signal produced by OA6 at a V_{REF} terminal, and combined with OA4 forms a fourth programmable inverting voltage attenuator. The output signal produced by OA4 is provided to the inverting input terminal of an op amp OA8, configured as an inverting amplifier, through a resistance value R2. A feedback resistance value R3 is coupled between an output terminal of OA8 and the inverting input terminal. As a result, a damping factor ξ of the system is given by:

$$ζ = ( \frac{D4}{{2}^{n + 1}} ) ( \frac{R3}{R2} ) ( \frac{R4}{R6} )$$

The signal produced by OA1 is provided to an inverting input terminal of OA5 through a resistance value R5, and the signal produced by OA8 is provided as a feedback signal to the inverting input terminal of OA5 through a resistance value R6. The low pass output signal produced by OA7 is also provided as a feedback signal to the inverting input terminal of OA5 through a resistance value R7. OA5 has a feedback resistance value R4 coupled between an output terminal and the inverting input terminal. Resistance values R4, R5, R6, and R7 may be equal. MDAC1-MDAC4 may be MDACs of a device model DAC8408 manufactured by Analog Devices (Norwood, Mass.). Op amps OA1-OA8 may be op amps of device models OP482 made by Analog Devices.

All electrical circuits generate non-periodic voltages termed “noise”. Most circuits are designed to keep the magnitudes of wanted signals as large as possible with respect to the magnitudes of unwanted signals (e.g., noise voltages). While digital values D1-D4 can be changed in order to vary key filter characteristics of state variable filter 10, the amount of noise voltage generated within state variable filter 10 is relatively high and stays about the same regardless of digital values D1-D4. This is true in part because the values of R1 and C1, which determine the noise bandwidths of the two inverting integrators including OA6 and OA7, remain the same. In addition, the band pass output signal produced by the first integrator is attenuated before being provided to the second integrator. Noise voltage reduction in the low pass output signal via negative feedback through resistance R7 is thus mitigated. As a result, the noise level within the low pass output signal is higher than the noise levels within the high and band pass output signals.

The usefulness of exemplary programmable state variable filter 10 is compromised when wanted signal magnitudes do not substantially exceed the relatively high noise levels generated within state variable filter 10. This is especially true in the case of the low pass output signal as the low pass output signal has the highest noise level. It would thus be beneficial to have an improved programmable state variable filter generating lower output noise levels than those of known programmable state variable filters (e.g., exemplary programmable state variable filter 10).

### SUMMARY OF THE INVENTION

An active state variable filter is presented including several programmable variable resistors. Each programmable variable resistor is coupled to receive a digital value and configured to provide an electrical resistance corresponding to the digital value between a pair of terminals. The programmable variable resistors are programmed with digital values to achieve desired filter characteristics. The state variable filter including programmable variable resistors may be formed upon a monolithic semiconductor substrate.

In one embodiment, each programmable variable resistor includes multiple branch circuits extending between a first terminal and a second terminal. Each branch circuit includes an electrical resistor and an electrical switch connected in series. The programmable variable resistor may also include a memory unit for storing a digital value, and control logic coupled to the electrical switch in each of the branch circuits. The control logic may control the electrical switch in each of the branch circuits dependent upon the digital value stored within the memory unit. As a result, an electrical resistance corresponding to the digital value may be produced between the first and second terminals.

The electrical switch in each of the branch circuits may be a bilateral electrical switch such that electrical current is conducted in a similar manner through the programmable variable resistor from the first terminal to the second terminal, and from the second terminal to the first terminal. The electrical switch in each of the branch circuits may be a microelectromechanical systems (MEMS) switch. The MEMS switch may include a stationary contact, a moving contact, and an actuator. The moving contact may include a beam extending over the actuator and the stationary contact such that an end of the beam is located above the stationary contact. An electrical voltage applied between the actuator and the moving contact may produce an electrostatic force between the actuator and the beam. The electrostatic force may cause the beam to move toward the actuator such that the end of the beam comes into electrical contact with the stationary contact.

Each of the electrical switches within the branch circuits may have a first terminal, a second terminal, and a control terminal. Each of the electrical switches may receive a different control signal from the control logic at the control terminal. Each of the electrical switches may be in either an open state or a closed state dependent upon the received control signal. Each of the electrical switches may offer a relatively high electrical resistance (e.g., greater than about 1.0×10¹⁰ ohms) between the first and second terminals when in the open state, and a relatively low electrical resistance (e.g., less than about 20 ohms) between the first and second terminals when in the closed state.

The control logic may receive a digital value and a control signal, and may store the digital value within the memory unit in response to the control signal. The programmable variable resistor may include n branch circuits, and the value of the electrical resistor in branch circuit n may be 2⁽ⁿ⁻¹⁾ times a selected base resistance value.

In an alternate embodiment, the programmable variable resistor may include multiple subcircuits connected in series between the first terminal and the second terminal. Each subcircuit may include an electrical resistor and an electrical switch connected in parallel. The alternate embodiment of the programmable variable resistor may also include the memory unit described above and control logic coupled to the electrical switch in each of the subcircuits. The control logic may be configured to control the electrical switch in each of the subcircuits dependent upon the digital value stored within the memory unit such that an electrical resistance corresponding to the digital value is produced between the first and second terminals. As described above, the electrical switch in each of the subcircuits may be a bilateral electrical switch such as a MEMS switch. The programmable variable resistor may include n subcircuits, and the value of the electrical resistor in subcircuit n may be 2⁽ⁿ⁻¹⁾ times a selected base resistance value.

The active state variable filter may include a first summing circuit, a first and second integrator circuits, and an amplifier circuit. The first summing circuit may receive an input signal, a low pass signal, and a band pass signal. The first summing circuit may perform a mathematical summing operation upon the input signal, the low pass signal, and the band pass signal thereby producing a high pass signal. The first integrator circuit may receive the high pass signal produced by the summing circuit and perform a mathematical integration function upon the high pass signal thereby producing an intermediate signal. The second integrator circuit may receive the intermediate signal produced by the first integrator circuit and perform a mathematical integration function upon the intermediate signal thereby producing the low pass signal. The amplifier circuit may receive the intermediate signal and amplify the intermediate signal thereby producing the band pass signal.

The first summing circuit and first and second integrator circuits may each include a programmable variable resistor as described above for programmably varying the filtering characteristics of the state variable filter. For example, programmable variable resistors within the first and second integrator circuits may determine time constants of the respective integrator circuits.

The state variable filter may also include a second summing circuit. The second summing circuit may receive the high pass and low pass signals, and perform a mathematical summing operation upon the high pass and low pass signals thereby producing a band reject signal.

The state variable filter may also include a third summing circuit. The third summing circuit may receive the high pass, low pass, and band pass signals, and may perform a mathematical summing operation upon the high pass, low pass, and band pass signals thereby producing a composite filter signal. The third summing circuit may employ programmable variable resistors, and may be used to achieve any desired second-order transfer function.

An instrumentation system is also presented comprising a signal conditioning subsystem including the state variable filter. The signal conditioning subsystem may receive an input signal from a transducer, and may use the state variable filter to filter the input signal, thereby producing conditioned measurement data. The instrumentation system may also include a computer coupled to the signal conditioning subsystem. The computer system may receive the conditioned measurement data produced by the signal conditioning subsystem and may store the conditioned measurement data.

### BRIEF DESCRIPTION OF THE DRAWINGS

A better understanding of the present invention can be obtained when the following detailed description of the preferred embodiment is considered in conjunction with the following drawings, in which:

FIG. 1 is a circuit diagram of an exemplary prior art state variable filter having digitally programmable characteristics;

FIG. 2 is a circuit diagram of one embodiment of a programmable state variable filter in accordance with the present invention, wherein the programmable state variable filter includes several programmable variable resistors;

FIG. 3 is a circuit diagram of an optional summing amplifier which may be added to the state variable filter of FIG. 2, wherein the optional summing amplifier includes several programmable variable resistors;

FIG. 4 is a diagram of one embodiment of a programmable variable resistor which may be representative of the programmable variable resistors of FIGS. 2 and 3, wherein the programmable variable resistor includes multiple electrical resistors and electrical switches;

FIG. 5 is a diagram of an alternate embodiment of a programmable variable resistor which may also be representative of the programmable variable resistors of FIGS. 2 and 3, wherein the programmable variable resistor includes multiple electrical resistors and electrical switches;

FIG. 6 is a side elevation view of an exemplary microelectromechanical systems (MEMS) switch which may be representative of the electrical switches of FIGS. 4 and 5;

FIG. 7 is a graph of the computer simulated frequency response of the state variable filter of FIG. 2 wherein the programmable variable resistors have been replaced by ideal multiplying digital to analog converters (MDAC)-operational amplifier (op amp) pairs forming voltage attenuators;

FIGS. 8, 9 and 10 are graphs of the simulated root mean square (RMS) magnitudes of the integrated noise voltages within the respective low pass, high pass, and band pass signals produced by the state variable filter of FIG. 2 versus frequency wherein the programmable variable resistors have been replaced by ideal MDAC-op amp pairs forming voltage aftenuators;

FIGS. 11, 12, and 13 are graphs of the simulated RMS magnitudes of the integrated noise voltages within the respective low pass, high pass, and band pass signals produced by the state variable filter of FIG. 2 versus frequency wherein the programmable variable resistors have been programmed to provide selected electrical resistance values in order to achieve the filtering characteristics of FIG. 7; and

FIG. 14 is a perspective view of a computer-based instrumentation system including the state variable filter of FIG. 2.

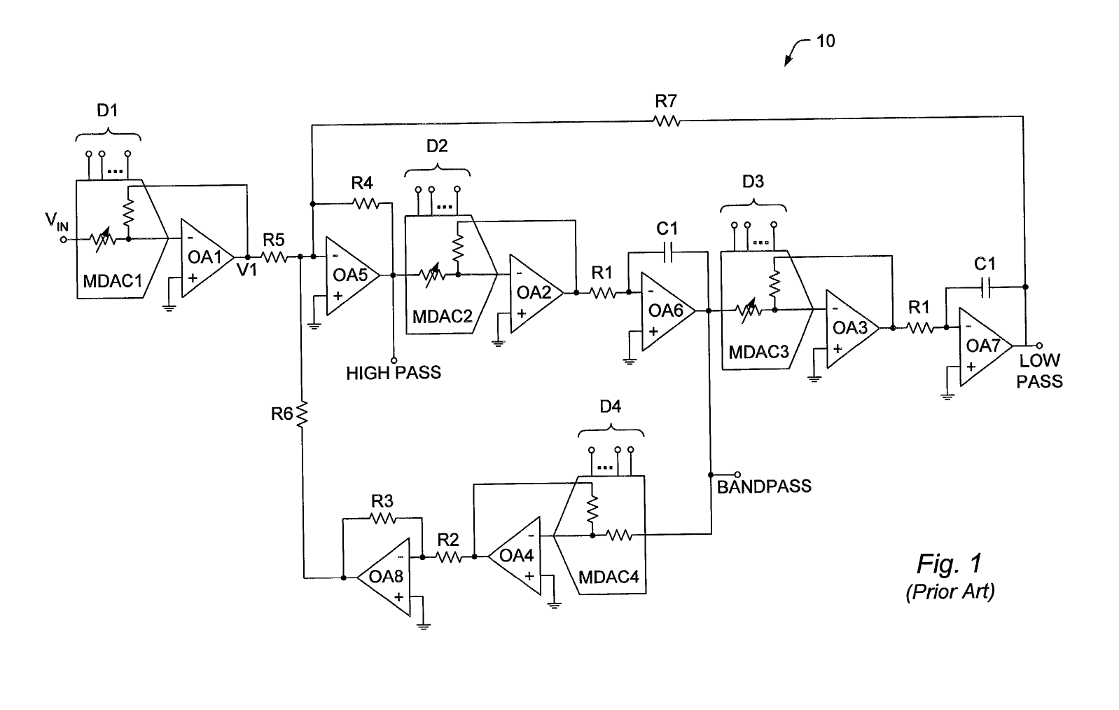

### DETAILED DESCRIPTION OF THE PREFERRED EMBODIMENT

State Variable Filter

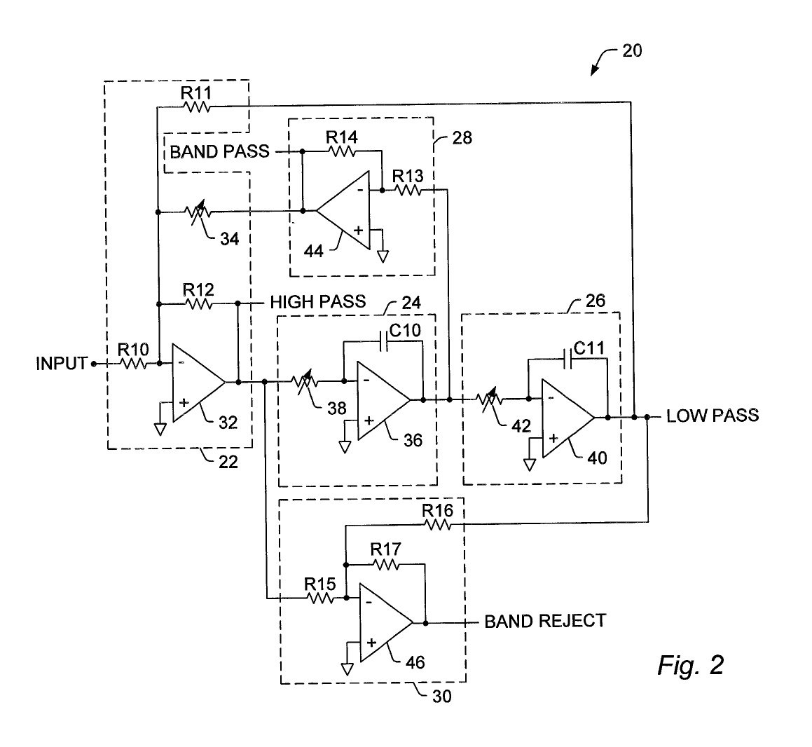

FIG. 2 is a circuit diagram of one embodiment of a programmable state variable filter 20 in accordance with the present invention. State variable filter 20 includes several operational amplifiers (i.e., op amps) which require a supply of electrical power during operation. State variable filter 20 is thus an active filter. State variable filter 20 includes a summing amplifier 22, a first integrator 24, a second integrator 26, and an inverting amplifier 28. State variable filter 20 also includes a second optional inverting amplifier 30.

Summing amplifier 22 includes an op amp 32 having a non-inverting input terminal connected to a ground reference potential. An inverting input terminal of op amp 32 receives an input signal through a resistor Ri0, a low pass signal through a resistor R11, and a band pass signal through a programmable variable resistor 34. As will be explained in more detail below, programmable variable resistor 34 receives a digital value and provides an electrical resistance corresponding to the digital value between a pair of terminals. A resistor R12 is connected between an output terminal of op amp 32 and the inverting input terminal. Summing amplifier 22 performs a mathematical summing operation upon the input signal (IN), the low pass signal (LP), and the band pass signal (BP) thereby producing a high pass signal (HP):

$$HP = - [ ( \frac{R12}{R10} ) \cdot IN + ( \frac{R12}{R11} ) \cdot LP + ( \frac{R12}{VR1} ) \cdot BP ]$$

where VR1 is the electrical resistance between the pair of terminals of programmable variable resistor 34.

First integrator 24 includes an op amp 36 having a non-inverting input terminal connected to the ground reference potential. An inverting input terminal of op amp 36 receives the high pass signal produced by summing amplifier 22 through a programmable variable resistor 38. A capacitor C10 is connected between an output terminal of op amp 36 and the inverting input terminal. First integrator 24 performs a mathematical integration function upon the high pass signal (HP) thereby producing an intermediate signal (IM):

$$IM = - ( \frac{1}{VR2 \cdot C10} ) \cdot \int HP ⅆ t$$

where VR2 is the electrical resistance provided by programmable variable resistor 38. Along with C10, electrical resistance VR2 provided by programmable variable resistor 38 determines the time constant of first integrator 24.

Second integrator 26 includes an op amp 40 having a non-inverting input terminal connected to the ground reference potential. An inverting input terminal of op amp 40 receives the intermediate signal produced by first integrator 24 through a programmable variable resistor 42. A capacitor C11 is connected between an output terminal of op amp 40 and the inverting input terminal. Second integrator 26 performs a mathematical integration function upon the intermediate signal (IM) thereby producing the low pass signal (LP):

$$LP = - ( \frac{1}{VR3 \cdot C11} ) \cdot \int IM ⅆ t$$

where VR3 is the electrical resistance provided by programmable variable resistor 42. Along with C11, electrical resistance VR3 provided by programmable variable resistor 42 determines the time constant of second integrator 26.

Inverting amplifier 28 includes an op amp 44 having a non-inverting input terminal connected to the ground reference potential. An inverting input terminal of op amp 44 receives the intermediate signal produced by first integrator 24 through a resistor R13. A resistor R14 is connected between an output terminal of op amp 44 and the inverting input terminal. Inverting amplifier 28 amplifies the intermediate signal (IM) produced by first integrator 24 thereby producing the band pass signal (BP):

$$BP = - ( \frac{R14}{R13} ) \cdot IM$$

The digital values provided to programmable variable resistors 34, 38, and 42 determine the corner frequencies fc of the low and high pass signals (center frequency fo of the band pass signal), the voltage gain G provided within the pass bands, and the Q of the low, high, and band pass signals. Using the component values shown in FIG. 2, equations for fc/fo, G, and ξ are:

$${f}_{c} = {f}_{o} = \frac{1}{2 π RC}$$

where VR2=VR3=R and C10=C11=C,

G1 where R10=R11=R12, and

$$ζ = \frac{R12}{2 \cdot VR1}$$

where R14=R13, and

where VR1, VR2, and VR3 are the electrical resistances provided by respective programmable variable resistors 34, 38, and 42.

Optional summing amplifier 30 includes an op amp 46 having a non-inverting input terminal connected to the ground reference potential. An inverting input terminal of op amp 46 receives the high pass signal through a resistor R15 and the low pass signal through a resistor R16. A resistor R17 is connected between an output terminal of op amp 46 and the inverting input terminal. Optional summing amplifier 22 performs a mathematical summing operation upon the high pass signal (HP) and the low pass signal (LP) thereby producing a band reject signal (BR):

$$BR = - [ ( \frac{R17}{R15} ) \cdot HP + ( \frac{R17}{R16} ) \cdot LP ]$$

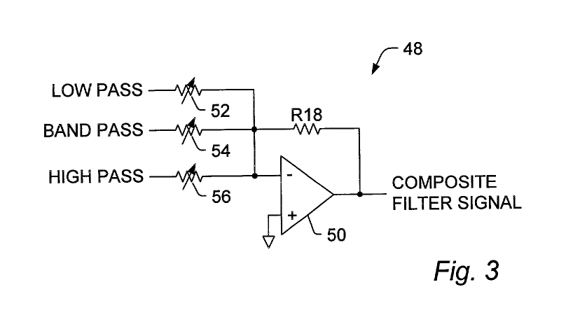

FIG. 3 is a circuit diagram of an optional summing amplifier 48 which may be added to state variable filter 20 of FIG. 2. Optional summing amplifier 48 includes an op amp 50 having a non-inverting input terminal connected to the ground reference potential. An inverting input terminal of op amp 50 receives the low pass signal through a programmable variable resistor 52, the band pass signal through a programmable variable resistor 54, and the high pass signal through a programmable variable resistor 56. A resistor R18 is connected between an output terminal of op amp 50 and the inverting input terminal. Optional summing amplifier 48 performs a mathematical summing operation upon the low pass signal (LP), the band pass signal (BP), and the high pass signal (HP) thereby producing a composite filter signal (CF):

$$CF = - [ ( \frac{R18}{VR4} ) \cdot LP + ( \frac{R18}{VR5} ) \cdot BP + ( \frac{R18}{VR6} ) \cdot HP ]$$

where VR4, VR5, and VR6 are the electrical resistances provided by respective programmable variable resistors 52, 54, and 56. With the addition of optional summing amplifier 48, state variable filter may achieve any desired second-order transfer function by providing appropriate digital values to programmable variable resistors 34, 38, 42, 52, 54, and 56.

Programmable Variable Resistor

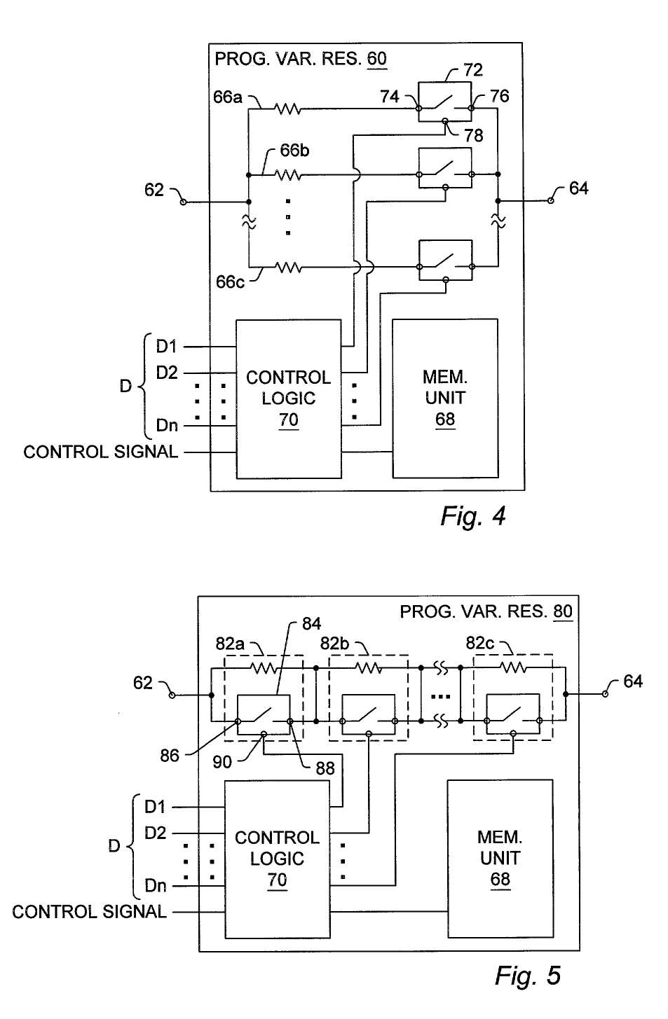

FIG. 4 is a diagram of one embodiment of a programmable variable resistor 60 which may be representative of programmable variable resistors 34, 38, 42, 52, 54, and 56 in FIGS. 2 and 3. Programmable variable resistor 60 receives a digital value D including n bits D1 through Dn. Programmable variable resistor 60 provides an electrical resistance corresponding to digital value D between a first terminal 62 and a second terminal 64. Programmable variable resistor 60 includes multiple branch circuits 66a-c extending between first terminal 62 and second terminal 64. Each branch circuit 66 includes an electrical resistor and an electrical switch connected in series. Programmable variable resistor 60 also includes a memory unit 68 for storing digital value D, and control logic 70 coupled to the electrical switch in each branch circuit 66. Control logic 70 controls the electrical switch in each branch circuit 66 dependent upon digital value D stored within memory unit 68 such that the electrical resistance corresponding to digital value D is produced between first terminal 62 and second terminal 64.

Control logic 70 may receive digital value D and a control signal as shown in FIG. 4. Control logic may store digital value D within memory unit 68 in response to the control signal. Memory unit 68 may include a sufficient number of memory elements or cells for storing bits D1 through Dn of digital value D, where n≧2. The memory cells may be volatile (e.g., static latches or random access memory cells) or non-volatile (e.g., electrically erasable programmable read only memory cells).

Each electrical switch within a branch circuit 66 receives a different control signal from control logic 70, and is either in an open state or a closed state dependent upon the received control signal. When in the open state, a given electrical switch offers a relatively high electrical resistance (e.g., greater than about 1.0×10¹⁰ ohms), substantially blocking a flow of electrical current through the corresponding branch circuit 66. When in the closed state, the given electrical switch offers a relatively low electrical resistance (e.g., less than about 20 ohms), freely permitting current to flow through the corresponding branch circuit 66. Programmable variable resistor 60 may include n branch circuits, and the value of the electrical resistor in branch circuit n may be 2⁽ⁿ⁻¹⁾ times a selected base resistance value.

An exemplary electrical switch 72 in branch circuit 66a has a first terminal 74, a second terminal 76, and a control terminal 78. The electrical resistor of branch circuit 66a is coupled between first terminal 62 of programmable variable resistor 60 and first terminal 74 of electrical switch 72. Second terminal 76 of electrical switch 72 is coupled to second terminal 64 of programmable variable resistor 60. Electrical switch 72 receives a control signal from control logic 70 at control terminal 78, and is either in the open state or the closed state dependent upon the received control signal. When in the open state, electrical switch 72 offers the relatively high electrical resistance described above between first terminal 74 and second terminal 76. Electrical switch 72 offers the relatively low electrical resistance described above between first terminal 74 and second terminal 76 when in the closed state. The electrical switches in branch circuits 66b and 66c are similarly configured. The electrical switches in branch circuits 66 are preferably bilateral electrical switches such that electrical current is conducted in a similar manner through programmable variable resistor 60 from first terminal 62 to second terminal 64, and from second terminal 64 to first terminal 62.

FIG. 5 is a diagram of an alternate embodiment of a programmable variable resistor 80 which may also be representative of programmable variable resistors 34, 38, 42, 52, 54, and 56 in FIGS. 2 and 3. Elements shared by programmable variable resistors 60 and 80 are labeled similarly. Like programmable variable resistor 60, programmable variable resistor 80 receives digital value D including n bits D1 through Dn and provides an electrical resistance corresponding to digital value D between first terminal 62 and second terminal 64.

Programmable variable resistor 80 includes multiple subcircuits 82a-c connected in series between first terminal 62 and second terminal 64. Each subcircuit 82 includes an electrical resistor and an electrical switch connected in parallel. Control logic 70 controls the electrical switch in each subcircuit 82 dependent upon digital value D stored within memory unit 68 such that the electrical resistance corresponding to digital value D is produced between first terminal 62 and second terminal 64.

Each electrical switch within a subcircuit 82 receives a different control signal from control logic 70, and is either in an open state or a closed state dependent upon the received control signal. When in the open state, a given electrical switch offers a relatively high electrical resistance (e.g., greater than about 1.0×10¹⁰ ohms), substantially requiring any current flowing between first terminal 62 and second terminal 64 to flow through the corresponding resistor of the subcircuit. When in the closed state, the given electrical switch offers a relatively low electrical resistance (e.g., less than about 20 ohms), substantially preventing any current flowing between first terminal 62 and second terminal 64 from flowing through the corresponding resistor of the subcircuit. Programmable variable resistor may include n subcircuits, and the value of the electrical resistor in subcircuit n may be 2⁽ⁿ⁻¹⁾ times a selected base resistance value.

An exemplary electrical switch 84 in subcircuit 82a has a first terminal 86, a second terminal 88, and a control terminal 90. First terminal 86 of electrical switch 84 is coupled to first terminal 62 of programmable variable resistor 80 and to one of two terminals of the resistor of subcircuit 82a. Second terminal 88 of electrical switch 84 is coupled to second terminal 64 of programmable variable resistor 80 through subcircuits 82b and 82c, and to the other terminal of the resistor of subcircuit 82a. Electrical switch 84 receives a control signal from control logic 70 at control terminal 90, and is either in the open state or the closed state dependent upon the received control signal. When in the open state, electrical switch 84 offers the relatively high electrical resistance described above between first terminal 86 and second terminal 88. Electrical switch 84 offers the relatively low electrical resistance described above between first terminal 86 and second terminal 88 when in the closed state. The electrical switches in subcircuits 82b and 82c are similarly configured. The electrical switches in subcircuits 82 are preferably bilateral electrical switches such that electrical current is conducted in a similar manner through programmable variable resistor 60 from first terminal 62 to second terminal 64, and from second terminal 64 to first terminal 62.

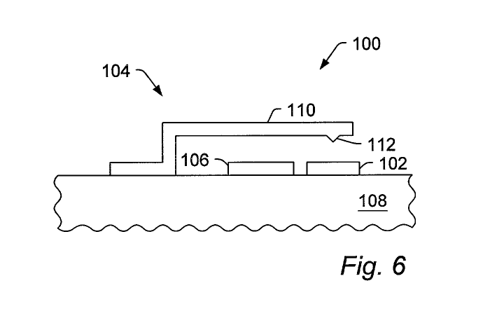

The electrical switches in branch circuits 66a-c and subcircuits 82a-c may be microelectromechanical systems (MEMS) switches. Methods of fabricating suitable MEMS switches are well known in the art. FIG. 6 is a side elevation view of an exemplary MEMS switch 100. MEMS switch 100 includes a stationary electrical contact 102, a moving electrical contact 104, and an actuator 106 formed upon a surface of a substrate 108. Moving contact 104 includes a beam 110 having two opposed ends. A first end of beam 110 is fixed to the surface of substrate 108. Beam 100 extends over actuator 106 and stationary contact 102 such that the second end of beam 110 is located above stationary contact 102. MEMS switch 100 is shown in the open state in FIG. 6. When in the open state, MEMS switch 100 offers a relatively high electrical resistance (e.g., greater than about 1.0×10¹⁰ ohms) between moving contact 104 and stationary contact 102.

MEMS switch 100 is transitioned from the open state to the closed state by applying an electrical voltage between actuator 106 and moving contact 104. The electrical voltage produces an electrostatic force between actuator 106 and beam 110. The electrostatic force causes beam 110 to move downward toward actuator 106 such that a tip 112 extending downward from beam 110 at the second end comes into electrical contact with stationary contact 102. When in the closed state, MEMS switch offers a relatively low electrical resistance (e.g., less than about 20 ohms) between moving contact 104 and stationary contact 102.

By virtue of the high voltage gains of the op amps in FIG. 2, the inverting input terminals of the op amps of state variable filter 20 are “virtually” maintained at the ground reference potential to which the non-inverting input terminals are connected. Moving contacts 104 of MEMS switches employed within programmable variable resistors of state variable filter 20 may advantageously be connected to the inverting input terminals of the op amps, thus facilitating the application of electrical voltages between actuators 106 and moving contacts 104. For example, the inverting input terminals of op amps 32, 36, and 40 are virtually maintained at the ground reference potential. Moving contacts 104 of MEMS switches employed within programmable variable resistors 34, 38, and 42 may be connected to the inverting input terminals of respective op amps 32, 36, and 40, thus facilitating the application of electrical voltages between actuators 106 and moving contacts 104 of the MEMS switches. Similarly, moving contacts 104 of MEMS switches employed within programmable variable resistors 52, 54, and 56 of optional summing amplifier 48 may be connected to the inverting input terminal op amp 50.

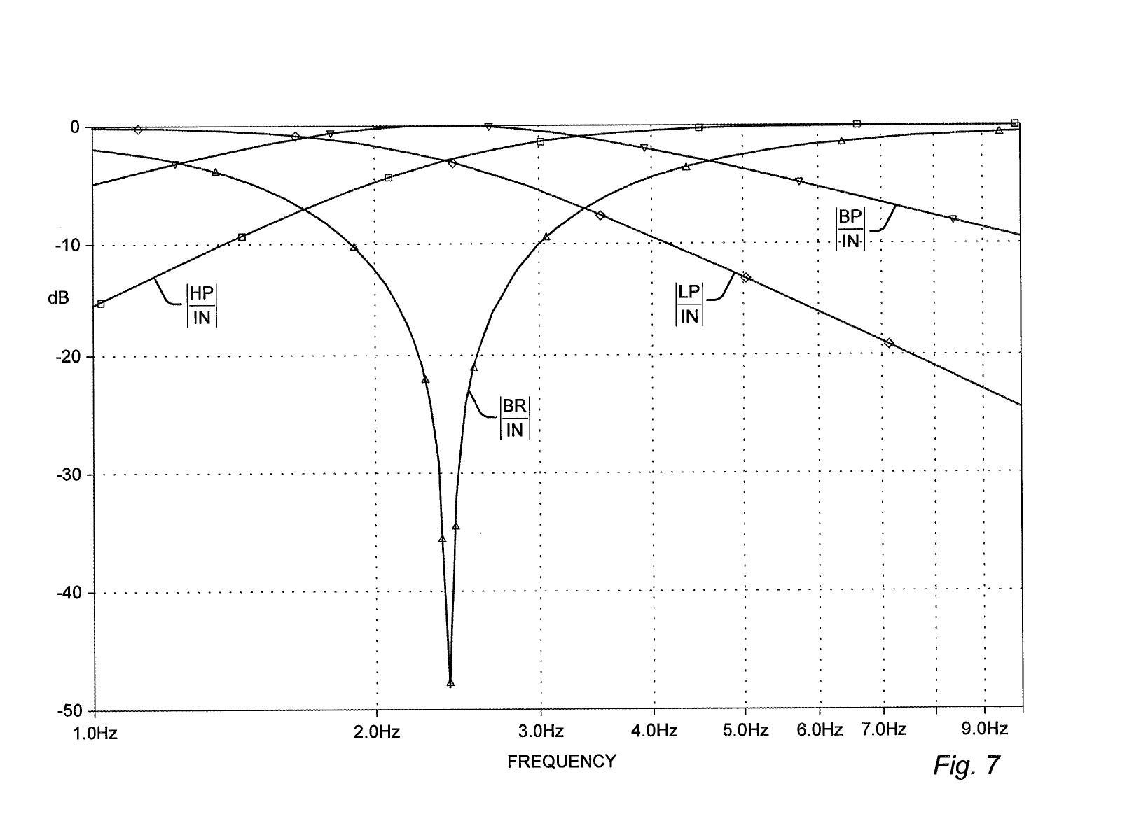

FIG. 7 is a graph of the computer simulated frequency response of state variable filter 20 of FIG. 2 wherein programmable variable resistors 34, 38, and 42 have been replaced by ideal MDAC-op amp pairs forming voltage attenuators as described above. In FIG. 7, the MDACs of the MDAC-op amp pairs have been programmed to provide corner Frequencies fc of the low and high pass signals (center frequency fo of the band pass and band reject signals) of 2.4 Hz, voltage gains G of 1.0 (0 decibels or dB) within the pass bands, and damping factors ξ of 1.0.

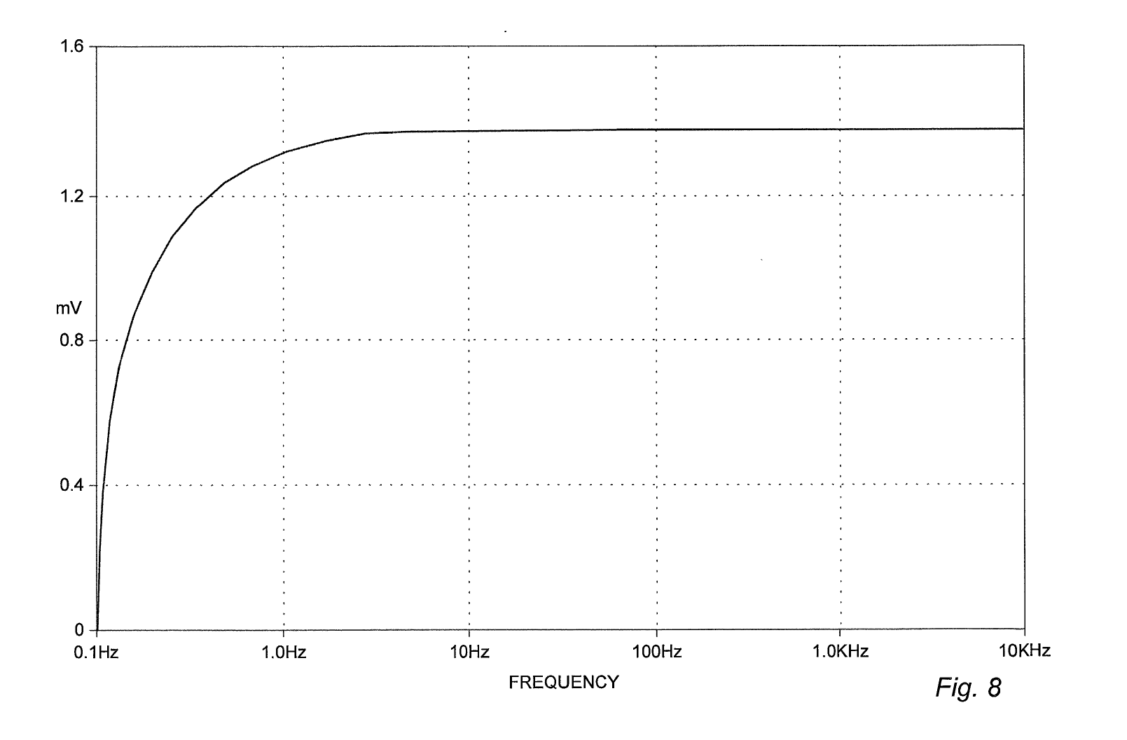

FIG. 8 is a graph of the simulated root mean square (RMS) magnitude of the integrated noise voltage within the low pass signal produced by state variable filter 20 versus frequency wherein programmable variable resistors 34, 38, and 42 have been replaced by ideal MDAC-op amp pairs forming voltage attenuators as described above. The MDACs of the MDAC-op amp pairs have been programmed to provide the same corner frequencies fc of the low and high pass signals (center frequency fo of the band pass and band reject signals) of 2.4 Hz, voltage gains G, and Qs as described in regard to FIG. 7. FIG. 8 shows that the simulated magnitude of the integrated noise voltage within the low pass signal produced by state variable filter 20 increases from about 0.0 millivolts (mV) at approximately 0.1 Hertz (Hz) to a substantially constant value of about 1.38 mV above approximately 3.0 Hz. The peak-to-peak noise voltage magnitudes within the pass band of the low pass signal are considered relatively high. For example, at 1.0 Hz, the peak-to-peak noise voltage within the low pass signal is greater than 1.3 mV. An input signal voltage of greater than 4.11 volts peak-to-peak is required in order to obtain a 70 dB signal to noise ratio at 1.0 Hz.

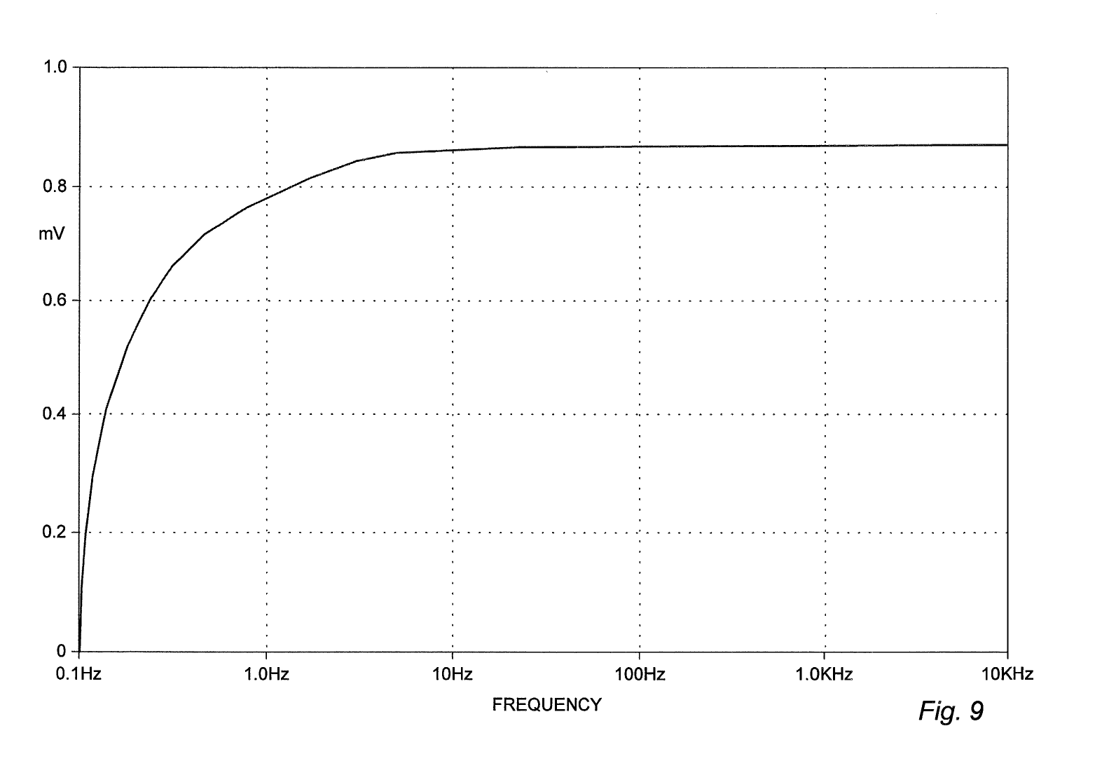

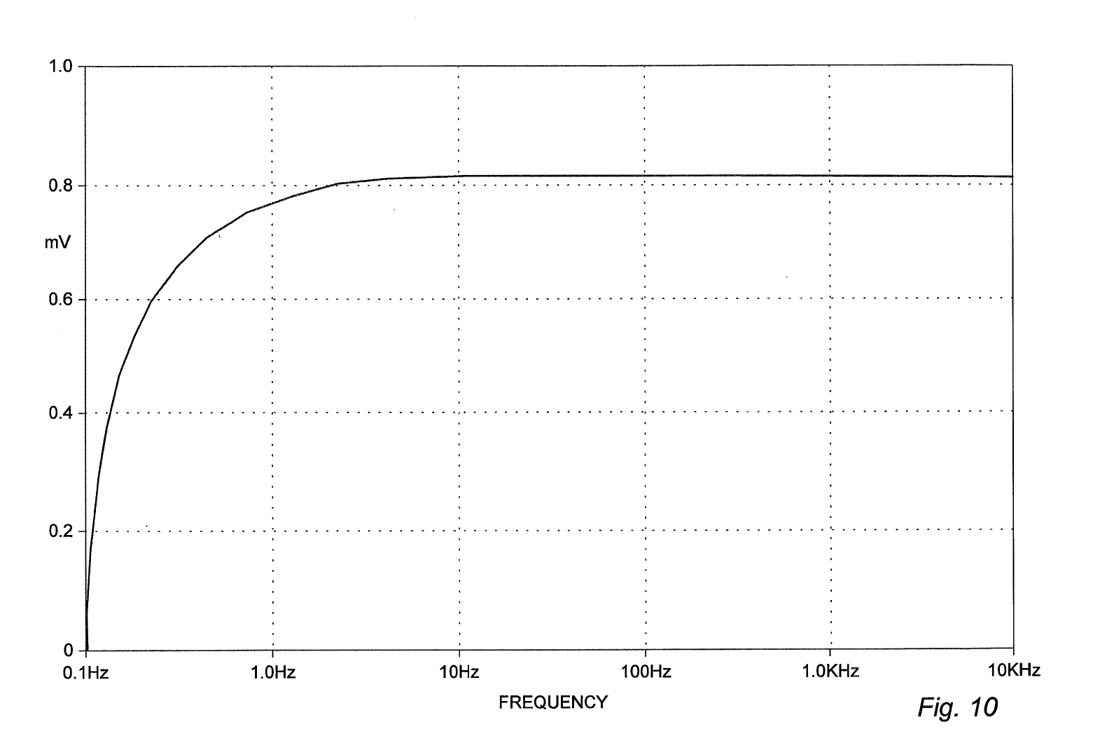

FIGS. 9 and 10 are graphs of the simulated RMS magnitudes of the integrated noise voltages within the respective high pass and band pass signals produced by state variable filter 20 versus frequency wherein programmable variable resistors 34, 38, and 42 have been replaced by ideal MDAC-op amp pairs forming voltage attenuators as described above. The MDACs of the MDAC-op amp pairs have been programmed to provide the same corner frequencies fc of the low and high pass signals (center frequency fo of the band pass and band reject signals) of 2.4 Hz, voltage gains G, and Qs as described in regard to FIG. 8. FIGS. 9 and 10 show that the simulated magnitudes of the integrated noise voltages within the respective high pass and band pass signals produced by state variable filter 20 increase from about 0.0 mV at approximately 0.1 Hz to substantially constant values greater than about 0.80 mV above approximately 5.0 Hz. The peak-to-peak noise voltage magnitudes within the pass bands of the high pass and band pass signals are considered relatively high for the reasons stated above.

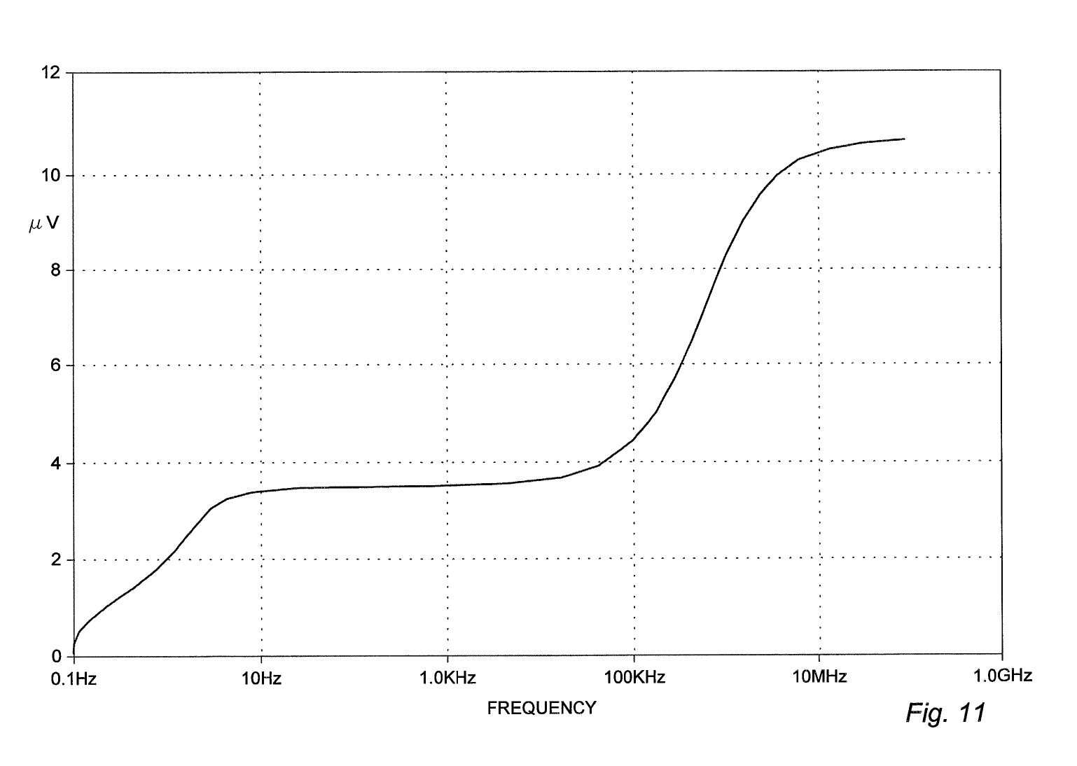

FIG. 11 is a graph of the simulated RMS magnitude of the integrated noise voltage within the low pass signal produced by state variable filter 20 versus frequency wherein programmable variable resistors 34, 38, and 42 have been programmed to provide selected electrical resistance values in order to achieve the same corner frequencies fc of the low and high pass signals (center frequency fo of the band pass and band reject signals) of 2.4 Hz, voltage gains G, and Qs as described in regard to FIG. 7. FIG. 11 shows that the simulated magnitude of noise voltage within the low pass signal produced by state variable filter 20 increases from about 0.0 microvolts (IV) at approximately 0.1 Hz to about approximately 3.5 μV at approximately 10.0 Hz, remains at about 3.5 μV between 10.0 Hz and approximately 20.0 kHz, and increases from about 3.5 μV at approximately 20.0 kHz to about 10.6 μV at approximately 100.0 megaHertz (MHz). The RMS noise voltage magnitudes within the pass band of the low pass signal are considerably lower than, and a substantial improvement over, the relatively high noise voltage magnitudes of FIG. 8. For example, at 1.0 Hz in FIG. 11, the noise voltage within the low pass signal is about 2.0 μV RMS. An input signal voltage of only 6.3 mV RMS is required in order to obtain a 70 dB signal to noise ratio at 1.0 Hz.

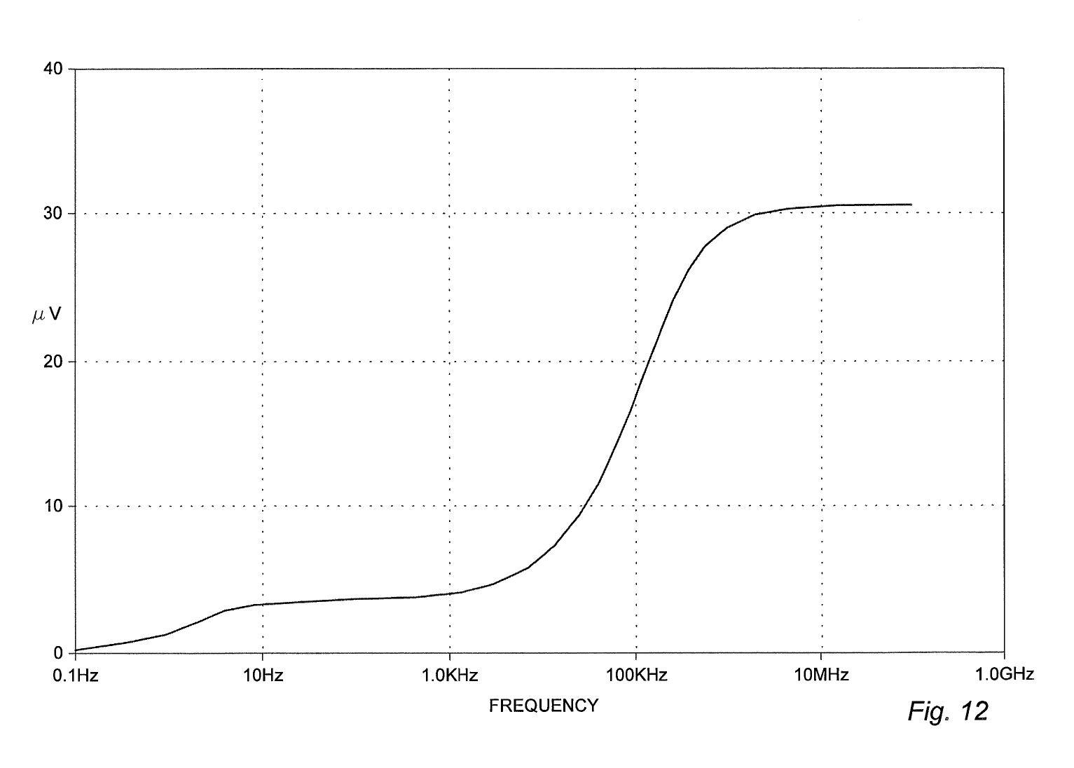

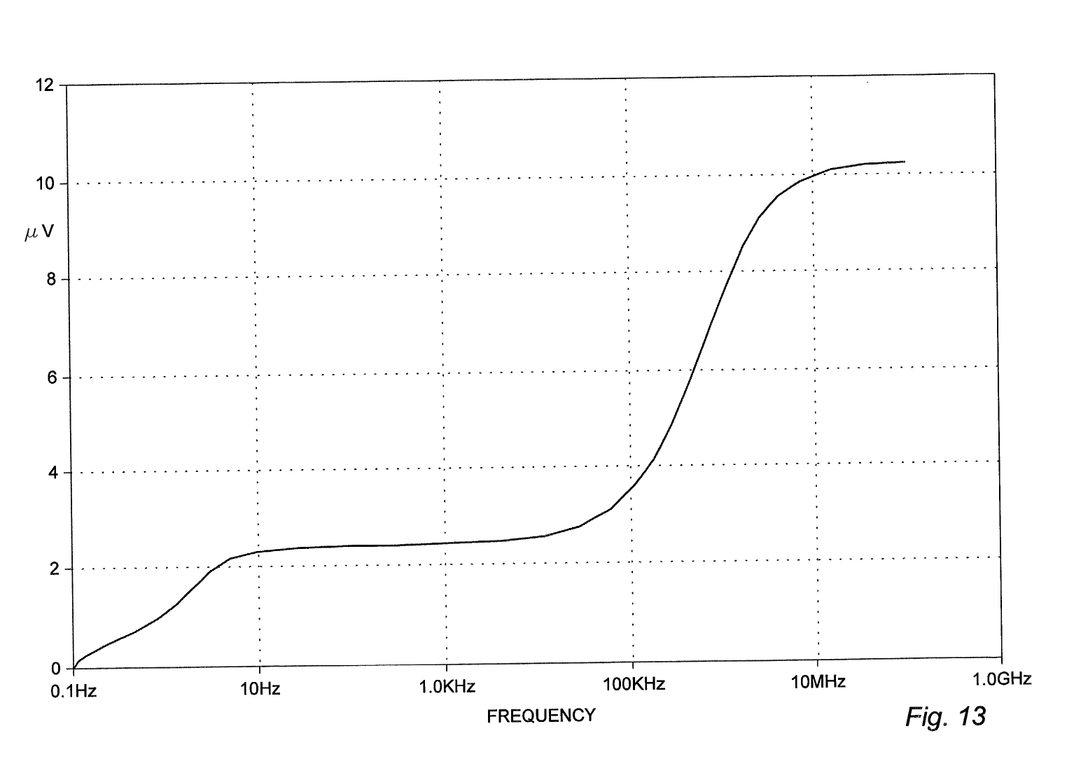

FIGS. 12 and 13 are graphs of the simulated RMS magnitudes of the integrated noise voltages within the respective high pass and band pass signals produced by state variable filter 20 versus frequency wherein programmable variable resistors 34, 38, and 42 have been programmed to provide selected electrical resistance values in order to achieve the same corner frequencies fc of the low and high pass signals (center frequency fo of the band pass and band reject signals) of 2.4 Hz, voltage gains G, and Qs as described in regard to FIG. 11. FIGS. 12 and 13 show that the simulated magnitudes of noise voltages within the respective high pass and band pass signals produced by state variable filter 20 with programmable variable resistors 34, 38, and 42 are considerably lower than, and a substantial improvements over, the relatively high RMS noise voltage magnitudes of respective FIGS. 10 and 11.

Instrumentation System

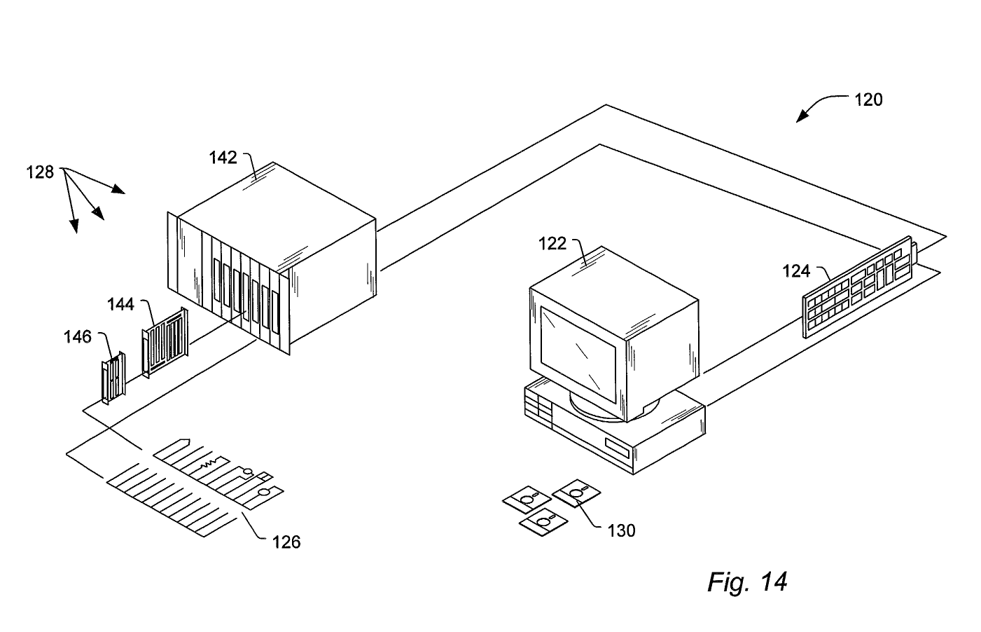

FIG. 14 is a perspective view of a computer-based instrumentation system 120 including state variable filter 20 described above. It is noted that state variable filter 20 may also be comprised in any number of various systems which use analog signal filters. Thus FIG. 14 is illustrative only, and various other embodiments are contemplated.

Instrumentation system 120 includes a computer 122, an instrumentation device or board 124, one or more transducers 126, signal conditioning subsystem 128, and storage media 130. Signal conditioning subsystem 128 may include one or more signal conditioning modules 144 and one or more terminal blocks 146 housed within a chassis 142. Transducers 126 convert one or more measurands (e.g., force, pressure, or acceleration) to electrical measurement signals. Transducers 126 may be coupled to signal conditioning subsystem 128 by wires or cables, and may provide the measurement signals to signal conditioning subsystem 128 via the wires or cables.

Signal conditioning subsystem 128 conditions (e.g., amplifies, filters, or performs d.c. level shifting upon) measurement signals received from transducers 126. Signal conditioning subsystem 128 includes at least one state variable filter 20 described above. For example, each signal conditioning module 144 may include state variable filter 20 for filtering a measurement signal produced by one of the transducers 126. Each state variable filter 20 may receive the measurement signal and simultaneously produce low pass, high pass, and band pass signals. Signal conditioning subsystem 128 may produce conditioned measurement data using the low pass, high pass, and/or band pass signals. Signal conditioning subsystem 128 may be coupled to computer system 122 and/or an instrumentation device or board 124 by wires or cables, and signal conditioning subsystem 128 may provide the conditioned measurement data to computer system 122 via the wires or cables.

Chassis 142 may be a signal conditioning extensions for instrumentation (SCXI) chassis, signal conditioning modules 144 may be SCXI signal conditioning modules, and terminal blocks 146 may be SCXI terminal blocks. SCXI is an open architecture, multi-channel signal conditioning front-end system for instrumentation devices. SCXI includes an external chassis housing signal conditioning modules for amplifying, multiplexing, and isolating measurement signals. SCXI signal conditioning modules advantageously reduce the introduction of noise into measurement signals.

Computer 122 may comprise various standard components, including at least one central processing unit (CPU), memory, a hard drive, one or more buses, and a power supply. Computer 122 may execute operating system and other software. Computer may store conditioned measurement data received from signal conditioning subsystem 128 within the memory or upon storage media 130. Storage media 130 may include, for example, magnetic floppy disks.

Instrumentation device or card 124 may be any of various types, such as a data acquisition (DAQ) device or card, a multimeter card, a voltmeter card, etc. In FIG. 14, instrumentation device or card 124 is shown external to computer system 122 for illustrative purposes. Instrument device or board 124 may be coupled to an input/output (I/O) port of computer system 122, or adapted for insertion into an expansion slot of computer system 122. Alternately, instrumentation device or board 124 may be coupled to computer 122 by a VME extensions for instrumentation (VXI) chassis and bus or a general purpose interface bus (GPIB).

Although the system and method of the present invention has been described in connection with the preferred embodiment, it is not intended to be limited to the specific form set forth herein, but on the contrary, it is intended to cover such alternatives, modifications, and equivalents, as can be reasonably included within the spirit and scope of the invention as defined by the appended claims.

We claim:

1. An active filter, comprising:
a first summing circuit coupled to receive an input signal, a low pass signal, and a band pass signal, wherein the first summing circuit is configured to perform a mathematical summing operation upon the input signal, the low pass signal, and the band pass signal thereby producing a high pass signal;
a first integrator circuit coupled to receive the high pass signal produced by the summing circuit and configured to perform a mathematical integration function upon the high pass signal thereby producing an intermediate signal;
a second integrator circuit coupled to receive the intermediate signal produced by the first integrator circuit and configured to perform a mathematical integration function upon the intermediate signal thereby producing the low pass signal;
an amplifier circuit coupled to receive the intermediate signal and configured to amplify the intermediate signal thereby producing the band pass signal;
wherein the first integrator circuit comprises a programmable variable resistor which determines a time constant of the first integrator circuit, and wherein the programmable variable resistor is coupled to receive a digital value and configured to provide an electrical resistance corresponding to the digital value between a first terminal and a second terminal.

2. The active filter as recited in claim 1, wherein the programmable variable resistor comprises:
a plurality of branch circuits extending between the first terminal and the second terminal, wherein each branch circuit includes an electrical resistor and an electrical switch connected in series;
a memory unit for storing the digital value; and
control logic coupled to the electrical switch in each of the branch circuits, wherein the control logic is configured to control the electrical switch in each of the branch circuits dependent upon the digital value stored within the memory unit such that the electrical resistance corresponding to the digital value is produced between the first and second terminals.

3. The active filter as recited in claim 2 wherein the electrical switch in each of the branch circuits comprises a microelectromechanical systems (MEMS) switch.

4. The active filter as recited in claim 1, wherein the programmable variable resistor comprises:
a plurality of subcircuits connected in series between the first terminal and the second terminal, wherein each subcircuit includes an electrical resistor and an electrical switch connected in parallel;
a memory unit for storing the digital value; and
control logic coupled to the electrical switch in each of the subcircuits, wherein the control logic is configured to control the electrical switch in each of the subcircuits dependent upon the digital value stored within the memory unit such that an electrical resistance corresponding to the digital value is produced between the first and second terminals.

5. The active filter as recited in claim 4 wherein the electrical switch in each of the subcircuits comprises a microelectromechanical systems (MEMS) switch.

6. The active filter as recited in claim 1, further comprising a second summing circuit coupled to receive the high pass and low pass signals, wherein the second summing circuit is configured to perform a mathematical summing operation upon the high pass and low pass signals thereby producing a band reject signal.

7. The active filter as recited in claim 1, farther comprising a second summing circuit coupled to receive the high pass, low pass, and band pass signals, wherein the second summing circuit is configured to perform a mathematical summing operation upon the high pass, low pass, and band pass signals thereby producing a composite filter signal.

8. An instrumentation system, comprising:
a signal conditioning subsystem coupled to receive an input signal from a transducer, wherein the signal conditioning subsystem includes:
an active filter, comprising:
a first summing circuit coupled to receive the input signal, a low pass signal, and a band pass signal, wherein the first summing circuit is configured to perform a mathematical summing operation upon the input signal, the low pass signal, and the band pass signal thereby producing a high pass signal;
a first integrator circuit coupled to receive the high pass signal produced by the summing circuit and configured to perform a mathematical integration function upon the high pass signal thereby producing an intermediate signal;
a second integrator circuit coupled to receive the intermediate signal produced by the first integrator circuit and configured to perform a mathematical integration function upon the intermediate signal thereby producing the low pass signal;
an amplifier circuit coupled to receive the intermediate signal and configured to amplify the intermediate signal thereby producing the band pass signal; and
wherein the first integrator circuit comprises a programmable variable resistor which determines a time constant of the first integrator circuit, and wherein the programmable variable resistor is coupled to receive a digital value and configured to provide an electrical resistance corresponding to the digital value between a first terminal and a second terminal.

9. The instrumentation system as recited in claim 8 wherein the programmable variable resistor comprises:
a plurality of subcircuits connected in series between the first terminal and the second terminal, wherein each subcircuit includes an electrical resistor and an electrical switch connected in parallel;
a memory unit for storing the digital value; and
control logic coupled to the electrical switch in each of the subcircuits, wherein the control logic is configured to control the electrical switch in each of the subcircuits dependent upon the digital value stored within the memory unit such that an electrical resistance corresponding to the digital value is produced between the first and second terminals.

10. The instrumentation system as recited in claim 9, wherein the electrical switch in each of the subcircuits comprises a microelectromechanical systems (MEMS) switch.

11. The instrumentation system as recited in claim 8, further comprising a computer coupled to the signal conditioning subsystem, and wherein the signal conditioning subsystem produces measurement data, and wherein the computer system is configured to receive the measurement data from the signal conditioning subsystem and to store the measurement data.
